(19) United States
(12) Patent Application Publication
(10) Pub. No.: US 2026/0122949 A1
(43) Pub. Date: Apr. 30, 2026

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: EN-SHUO LIN, NEW TAIPEI CITY (TW); YAO-CHUNG CHANG, HSINCHU COUNTY (TW); SHIH-PANG CHANG, HSINCHU COUNTY (TW); CHUN-LIN TSAI, HSIN-CHU (TW); CHING YU CHEN, HSINCHU COUNTY (TW)

(21) Appl. No.: 18/925,105

(22) Filed: Oct. 24, 2024

(51) Int. Cl. H01L 29/778; H01L 21/02; H01L 27/088; H01L 29/06; H01L 29/10; H01L 29/20; H01L 29/40; H01L 29/423; H01L 29/66

(52) U.S. Cl. CPC H10D 30/475; H10D 30/015; H10D 62/124; H10D 62/364; H10D 62/8503; H10P 14/2905; H10P 14/3416; H10D 64/111; H10D 64/518; H10D 84/83

(57) ABSTRACT

The present disclosure provides a semiconductor structure and a method of forming the semiconductor structure. The semiconductor structure includes a silicon substrate, a first III-V semiconductor layer over the silicon substrate, a second III-V semiconductor layer over the first III-V semiconductor layer, a gate electrode over the second III-V semiconductor layer, and a source electrode and a drain electrode coupled to the second III-V semiconductor layer. A ratio of a thickness of the silicon substrate and a thickness of the first III-V semiconductor layer is between approximately 0.6% and approximately 0.8%.

### BACKGROUND

A high electron mobility transistor (HEMT) is a type of field-effect transistor that leverages the properties of Group III-Group V (III-V) semiconductor compounds, such as gallium nitride (GaN), to achieve high performance. Unlike traditional metal oxide semiconductor field effect transistors (MOSFETs), which use a doped region as a channel, HEMTs utilize a very thin layer known as a two-dimensional electron gas (2DEG) at a junction between two materials with different band gaps (a heterojunction). This 2DEG layer, characterized by highly mobile conducting electrons with high densities, provides a channel for a transistor, resulting in low resistivity and high electron mobility. Such properties enable HEMTs to transmit signals at high frequencies, making them suitable for high power and high frequency applications.

From an application point of view, HEMTs have many advantages. However, despite the valuable properties mentioned above, a number of challenges exist in connection with developing III-V semiconductor compound-based devices. Various techniques directed at configurations and materials of these III-V semiconductor compounds have been implemented in attempt to improve transistor device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1H are schematic drawings illustrating a semiconductor structure at various fabrication stages constructed according to aspects of the present disclosure in one or more embodiments.

FIGS. 2A to 2U are schematic drawings illustrating a semiconductor structure at various fabrication stages constructed according to aspects of the present disclosure in one or more embodiments.

FIG. 3 is a top view of a semiconductor structure in accordance with embodiments of the present disclosure.

FIG. 4 is a flowchart representing a method for forming a semiconductor structure according to aspects of one or more embodiments of the present disclosure.

FIG. 5 is a flowchart representing a method for forming a semiconductor structure according to aspects of one or more embodiments of the present disclosure.

FIG. 6A is a graph showing a height profile of a substrate prior to a grinding obtained from an atomic force microscopy (AFM), and FIG. 6B is a graph showing a height profile of the substrate after the grinding obtained from the AFM.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer or section from another. The terms such as “first”, “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

Group III-V semiconductor compounds, such as those used in HEMT devices, have become increasingly popular for integrated circuit applications, particularly in power devices. Gallium nitride on silicon (GaN-on-Si)-based devices, for instance, offer high electron mobility in a two-dimensional electron gas (2DEG) layer at the AlGaN/GaN heterostructure interface, which serves as a channel rather than having a doped region serve as a channel in MOSFET devices. GaN, a wide band gap semiconductor material, is notable for its high breakdown voltage, making it ideal for high-voltage and high-power applications. This high breakdown voltage allows devices such as HEMTs to operate at elevated voltages without breaking down, which is important for high-power field-effect and high-frequency transistors. The high electron mobility and large electron velocity in the 2DEG layer further enhance the device's efficiency in handling high voltages.

However, ensuring reliable high-voltage performance also necessitates addressing challenges related to material characteristics, which can affect device stability and performance. For example, the GaN layer has to be thick enough to sustain device performance in a high-voltage environment (i.e., an environment with a voltage greater than 2,400 V), and a substrate supporting or carrying a GaN layer having such thickness also needs to be thick enough to mitigate a stress issue. However, the thick GaN layer plus the thick substrate may not be able to meet requirements of a manufacturing foundry.

The present disclosure therefore provides a method for forming a semiconductor structure for a HEMT device. In some embodiments, a silicon substrate is used for forming a thick GaN layer, and a backside grinding operation is used to thin the substrate from its backside. Accordingly, the substrate provides sufficient support during the forming of the GaN layer, and the thinned substrate with the thick GaN layer is able to form the HEMT device in the fab module.

Some embodiments of the present disclosure can be adopted to a HEMT device, but the disclosure is not limited thereto. In some embodiments, a semiconductor structure can be used in various IC devices such as a high-power device, a field-effect transistor (FET) device, a light-emitting diode (LED) device, a high-frequency device, and other suitable IC devices.

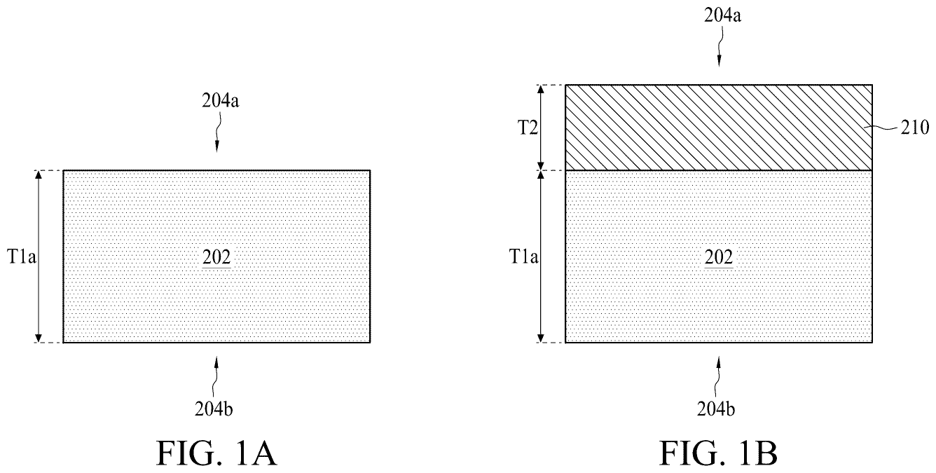

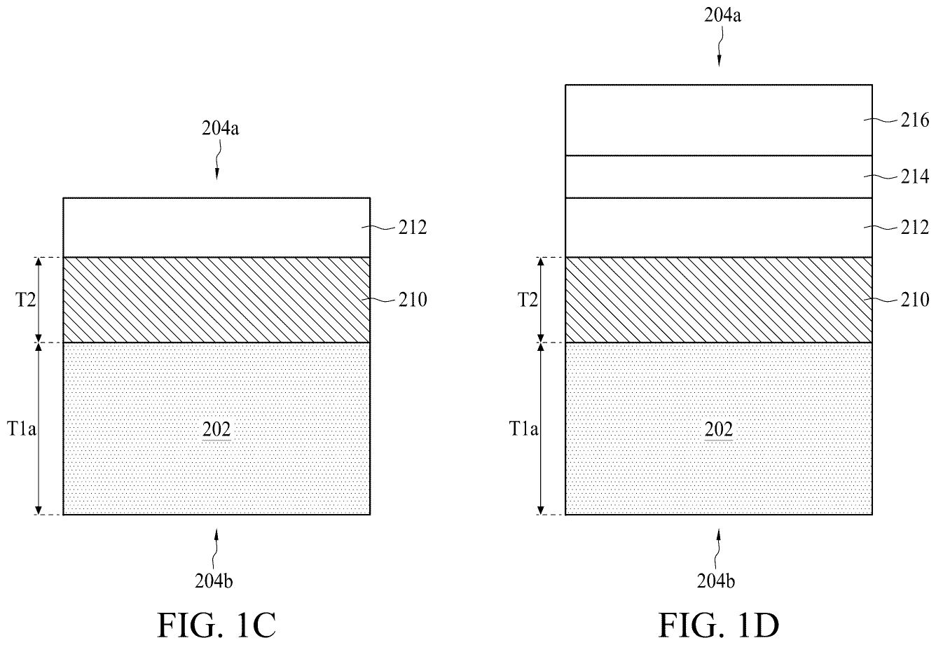

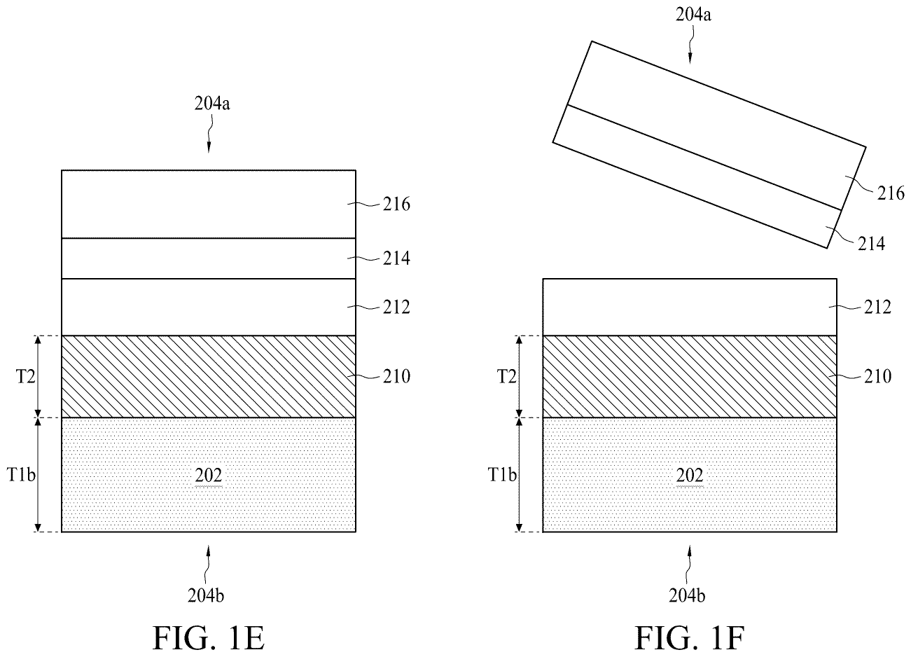

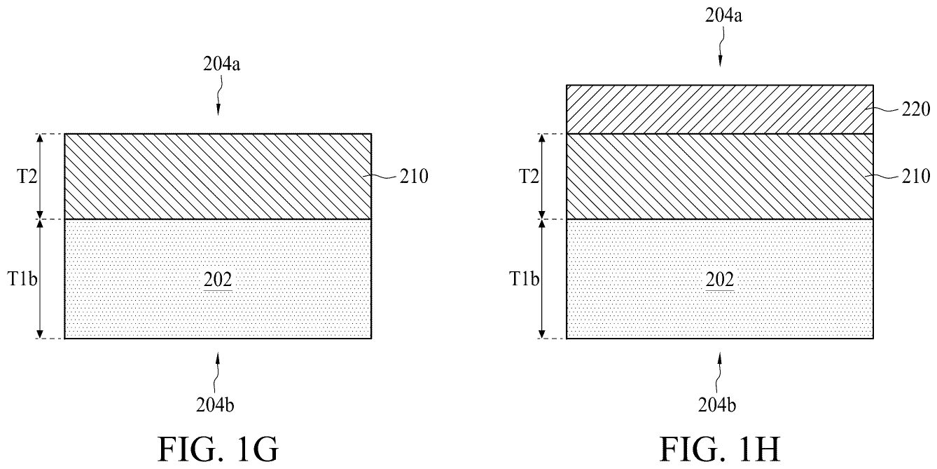

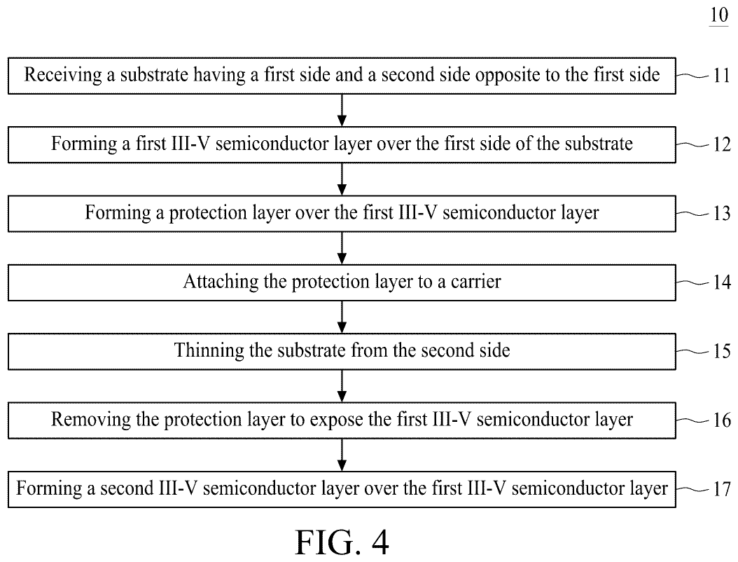

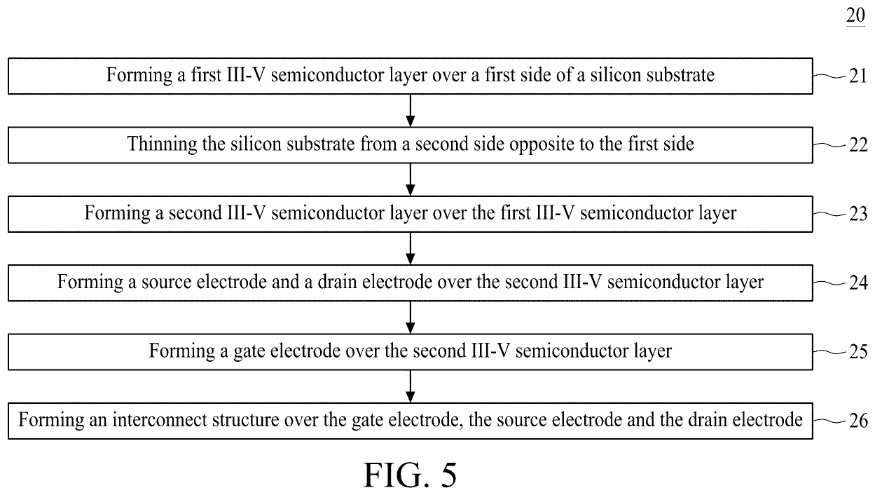

FIGS. 1A to 1H are schematic drawings illustrating a semiconductor structure at various fabrication stages constructed according to aspects of the present disclosure in one or more embodiments. FIGS. 4 and 5 are flowcharts representing methods for forming a semiconductor structure according to aspects of some embodiments of the present disclosure. In some embodiments, FIGS. 1A to 1H may represent the methods shown in FIGS. 4 and 5, but the disclosure is not limited thereto.

Referring to FIG. 1A, a substrate 202 is received or provided in accordance with operation 11. In some embodiments, the substrate 202 is a semiconductor substrate made of silicon. The silicon substrate 202 has a first side 204a and a second side 204b opposite to the first side 204a. In some embodiments, the silicon substrate 202 has a thickness T1a, and the thickness T1a is greater than 1.15 millimeter (mm). For example but not limited thereto, the thickness T1a of the silicon substrate 202 may be substantially 1.5 mm. In at least one embodiments, the silicon substrate 202 may be a (111) silicon wafer. That is, the silicon substrate 202 includes a top surface in a (111) plane, where the (111) is a crystalline plane represented by Miller indexes as known in the art. In some embodiments, the (111) silicon substrate 202 is chosen to provide a proper lattice mismatch with an overlying layer, but the disclosure is not limited thereto.

Referring to FIG. 1B, in some embodiments, a III-V semiconductor layer 210 is formed over the first side 204a of the substrate 202 in accordance with operation 12. In some embodiments, the III-V semiconductor layer 210 is a GaN layer. In some embodiments, the forming of the GaN layer over the silicon substrate 202 may include an epitaxial growth using metal organic chemical vapor deposition (MOCVD), also known as metal organic vapor phase epitaxy (MOVPE). In some embodiments, gallium-containing precursors such as trimethylgallium (TMG) or triethylgallium (TEG), and nitrogen-containing precursors such as ammonia (NH₃), tertiarybutylamine (TBAm), or phenyl hydrazine may be used in the MOCVD. In some embodiments, a thickness T2 of the III-V semiconductor layer 210 (i.e., the GaN layer) is greater than 7 micrometers (μm), but the disclosure is not limited thereto. In some embodiments, the thickness T2 of the III-V semiconductor layer 210 is between approximately 7 μm and approximately 9 μm, but the disclosure is not limited thereto. It should be noted that, in order to support the formation of the III-V semiconductor layer 210 with the thickness T2, the thickness T1a of the silicon substrate 202 needs to be greater than 1.15 mm. In some comparative approaches, when the thickness T1a of the silicon substrate 202 is less than 1.15 mm, the III-V semiconductor layer 210 and the underlying silicon substrate 202 suffer cracks due to stress generated during the forming of the III-V semiconductor layer 210. In some comparative approaches, a sapphire substrate or a silicon carbide (SiC) substrate, which respectively have a Moh's hardness greater than that of the silicon substrate 202, may be used to mitigate the stress issue. However, such approaches invariably incur greater cost. In contrast to those comparative approaches, an approach in which the silicon substrate 202 has the thickness T1a greater than 1.15 provides sufficient rigidness to mitigate the stress issue with a more economic material, i.e., silicon.

In some embodiments, the III-V semiconductor layer 210 may be undoped or unintentionally lightly doped with n-type dopants.

Additionally, in some embodiments, the III-V semiconductor layer 210 may be grown over a buffer layer and/or a transition layer on the silicon substrate 202, though not shown.

It should be understood that an apparatus, equipment, a system and/or tools are used for forming elements of a semiconductor integrated circuits. Such apparatus, equipment, systems and/or tools may have various limits for parameters, such as an overall thickness of a wafer, a width or a diameter of a wafer, etc. In some embodiments, an overall thickness of the silicon substrate 202 and the overlying III-V semiconductor layer 210 exceeds a thickness limit of the apparatus, equipment, system and/or tool used in subsequent processes. In other words, a structure in which the silicon substrate 202 has the thickness T1a and the III-V semiconductor layer 210 has the thickness T2 may be incompatible with the foundry.

Referring to FIG. 1C, in some embodiments, a protection layer 212 is formed over the III-V semiconductor layer 210 in operation 13. In some embodiments, the protection layer 212 includes a dielectric material, for example but not limited thereto, silicon oxide. In some embodiments, a thickness of the protection layer 212 is equal to or greater than 20,000 angstroms, but the disclosure is not limited thereto.

Referring to FIG. 1D, in some embodiments, the protection layer 212 is attached to a carrier 216 in operation 14. In some embodiments, the protection layer 212 is attached to the carrier 216 by an adhesive layer 214. The adhesive layer 214 may be, for example but not limited thereto, a UV tape. The carrier 216 may be, for example but not limited thereto, a chemical mechanical polishing (CMP) holder. The adhesive layer 214 helps to attach the protection layer 212 to the carrier 216, such that the protection layer 212, the III-V semiconductor layer 210 and the silicon substrate 202 are secured to the carrier 216, and the second side 204b of the silicon substrate 202 may be exposed for performing a grinding.

Referring to FIG. 1E, the silicon substrate 202 is thinned from the second side 204b in operation 15. In some embodiments, the thinning of the silicon substrate 202 includes a backside grinding, but the disclosure is not limited thereto. Accordingly, the thickness T1a of the silicon substrate 202 is reduced to a thickness T1b after the thinning. In some embodiments, a thickness difference between the first thickness T1a and the second thickness T1b is greater than 15%. In some embodiments, the thickness T1b of the substrate 202 after the thinning is less than 1.15 mm. In some embodiments, a ratio of the thickness T1b of the substrate after the thinning and the thickness T2 of the III-V semiconductor layer 210 may be between approximately 0.6% and approximately 0.8%. After the thinning, an overall thickness of the silicon substrate 202 and the overlying III-V semiconductor layer 210 is reduced. The reduced overall thickness makes the silicon substrate 202 and the overlying III-V semiconductor layer 210 suitable for forming other elements over the III-V semiconductor layer 210 in the foundry.

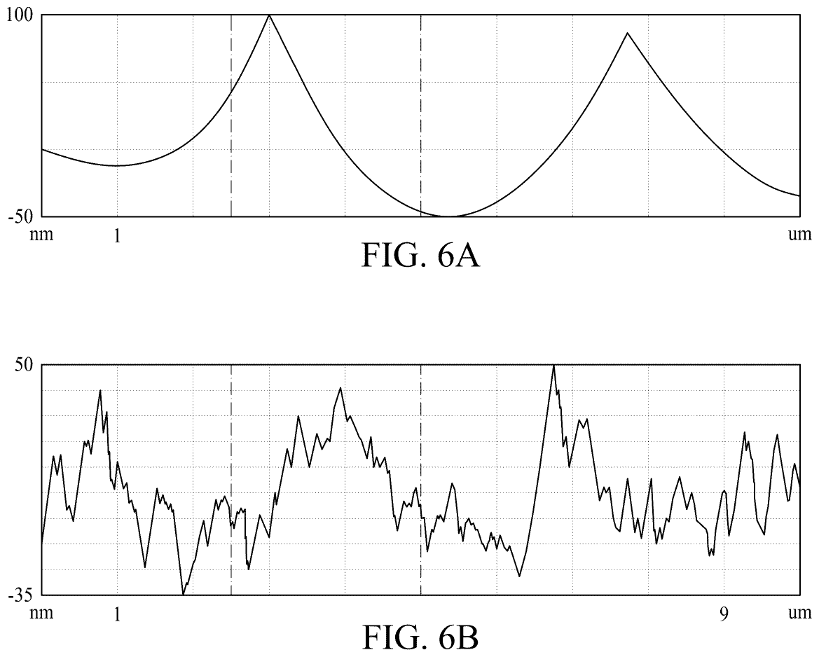

Please refer to FIGS. 6A and 6B, wherein FIG. 6A is a graph showing a height profile of a substrate prior to a thinning obtained from an atomic force microscopy (AFM), and FIG. 6B is a graph showing a height profile of the substrate after the thinning obtained from the AFM. In some embodiments, a height difference on the second side 204b of the silicon substrate 202 prior to the grinding is approximately 150 nm, and a height difference on the second side 204b of the silicon substrate 202 after the grinding is approximately 85 nm.

Referring to FIG. 1F, in some embodiments, the protection layer 212, the III-V semiconductor layer 210 and the silicon substrate are detached from the adhesive layer 214 and the carrier 216. Accordingly, the protection layer 212 is exposed.

Referring to FIG. 1G, in some embodiments, the protection layer 212 is removed to expose the III-V semiconductor layer 210 in operation 16.

Referring to FIG. 1H, in some embodiments, a III-V semiconductor layer 220 is formed over the III-V semiconductor layer 210 in operation 17. In some embodiments, the III-V semiconductor layer 220 includes a material different from that of the III-V semiconductor layer 210. For example, the III-V semiconductor layer 210 includes GaN, and the III-V semiconductor layer 220 includes aluminum gallium nitride (AlGaN). In some embodiments, the formation of the III-V semiconductor layer (i.e., the AlGaN layer) 220 over the III-V semiconductor layer (i.e., the GaN layer) 210, may include epitaxially growing the AlGaN layer 220 using metal-organic chemical vapor deposition (MOCVD). In some embodiments, appropriate aluminum, nitrogen, and gallium precursors are used in such deposition. The aluminum precursor can be trimethylaluminum (TMA), triethylaluminum (TEA), or other suitable chemicals. The gallium precursors may include trimethylgallium (TMG) or triethylgallium (TEG), among others. The nitrogen precursors can be phenyl hydrazine, dimethylhydrazine, tertiarybutylamine, ammonia, or another suitable chemical. The AlGaN layer can be represented as AlxGal-xN, where the value of x ranges from 0.05 to 1. A thickness of the III-V semiconductor layer 220 can be less than 30 nm. In some embodiments, the thickness of the III-V semiconductor layer 220 may be between about 5 nm and about 30 nm, but the disclosure is not limited thereto. In some embodiments, the III-V semiconductor layer 220 may be in contact with the III-V semiconductor layer 210.

In some embodiments, the III-V semiconductor layer (i.e., the AlGaN layer) 220 has a greater band gap compared to the III-V semiconductor layer (i.e., the GaN layer) 210. This band gap discontinuity, along with the piezo-electric effect, creates a very thin layer of highly mobile conducting electrons at the interface of the GaN and AlGaN layers. This thin layer is known as a two-dimensional electron gas (2-DEG) layer and forms a carrier channel. The 2-DEG layer is located in the GaN layer near the interface with the AlGaN layer.

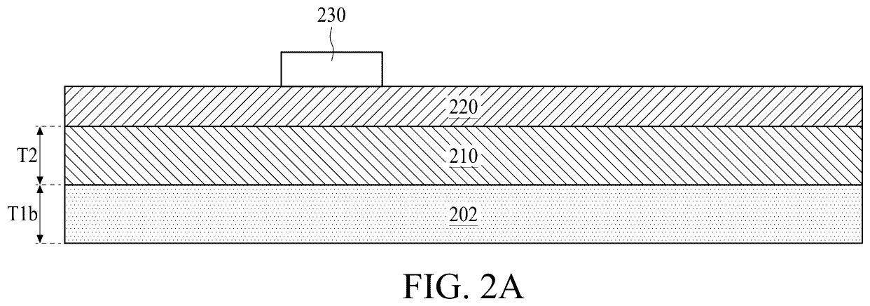

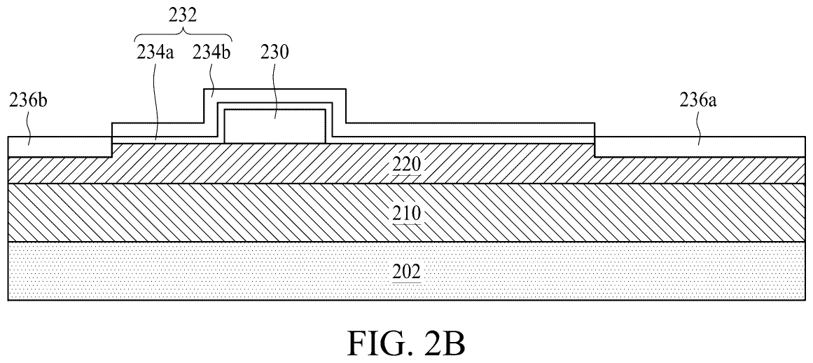

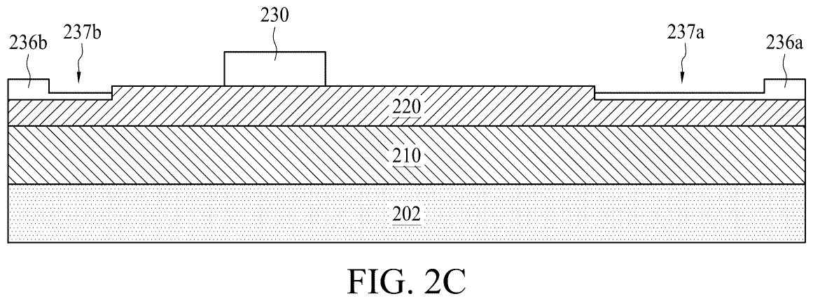

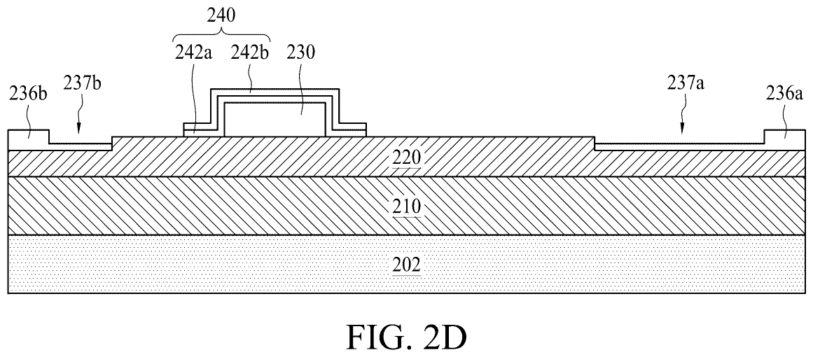

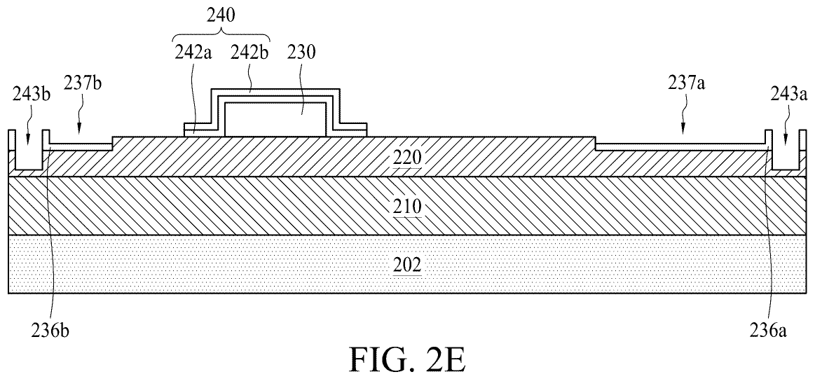

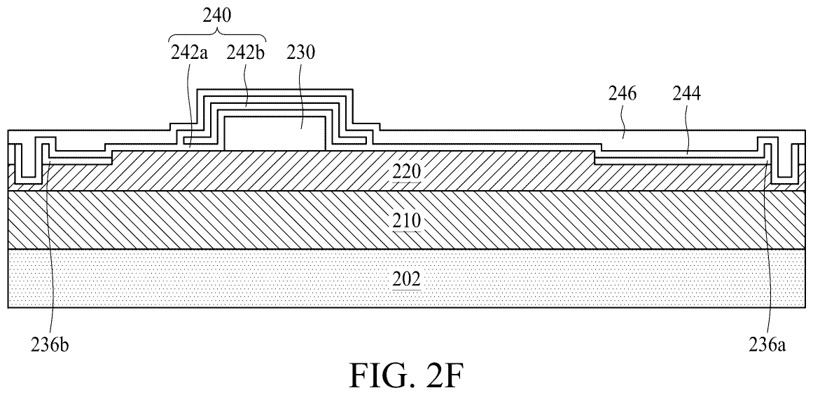

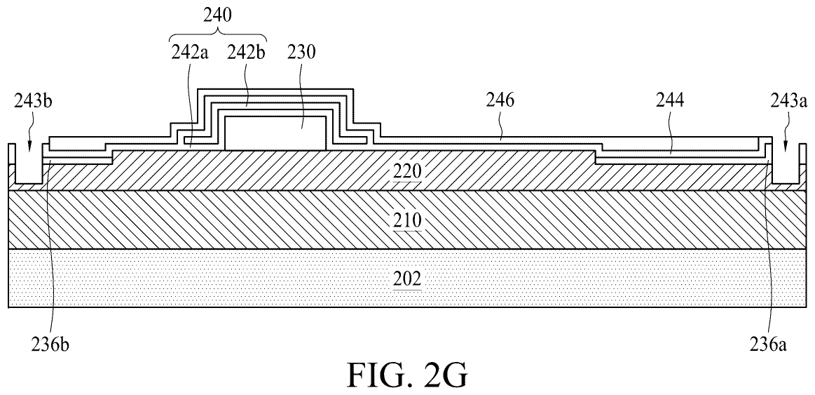

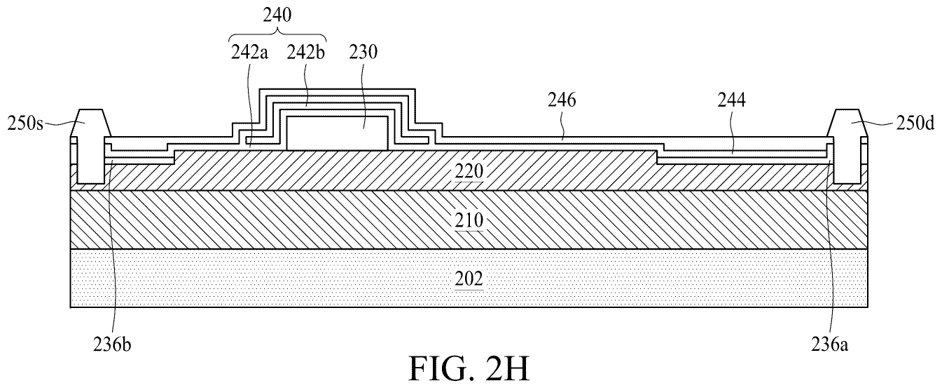

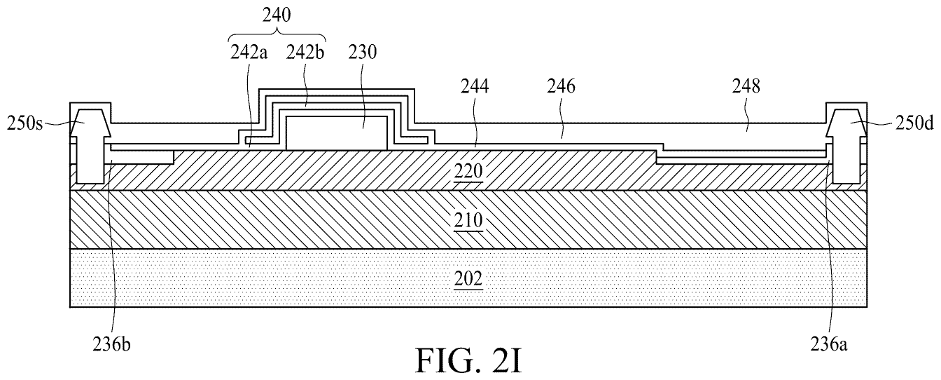

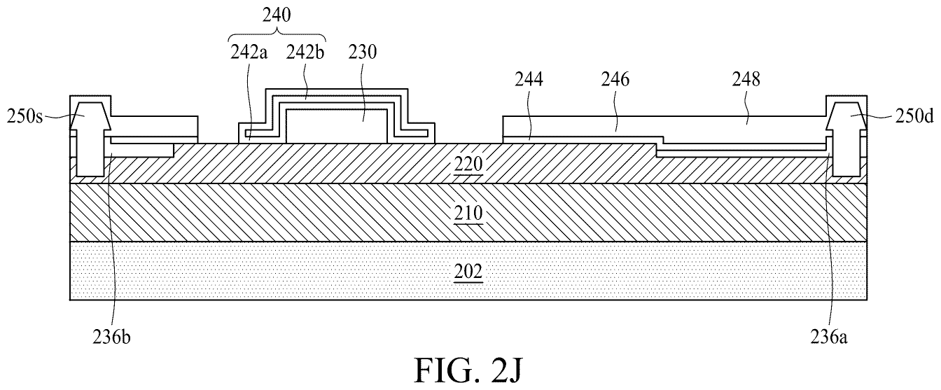

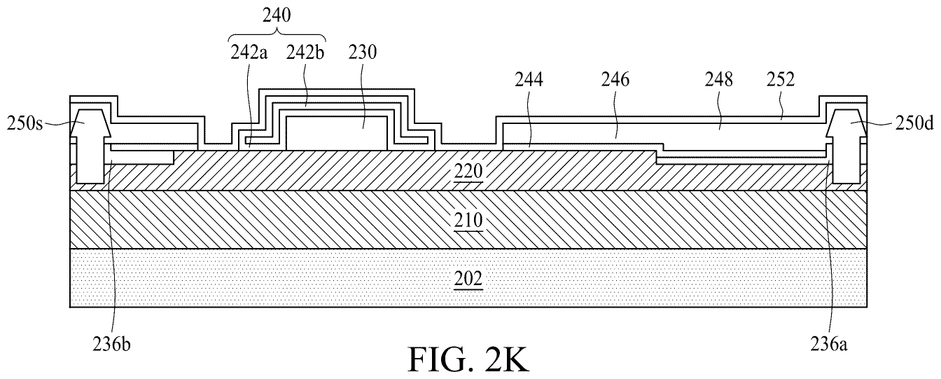

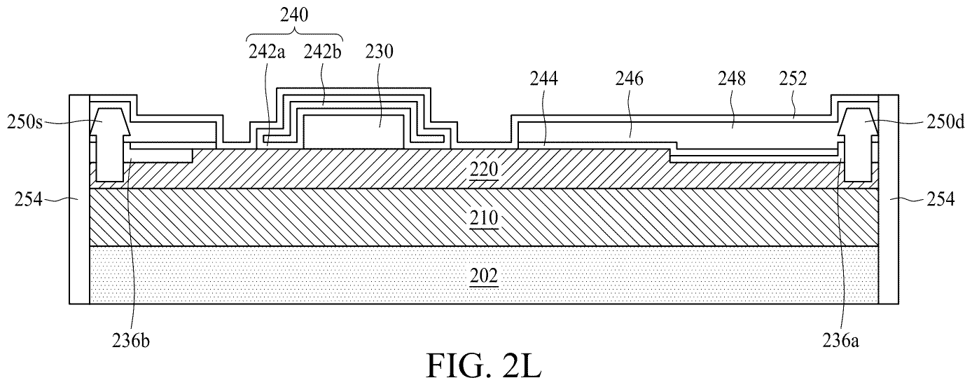

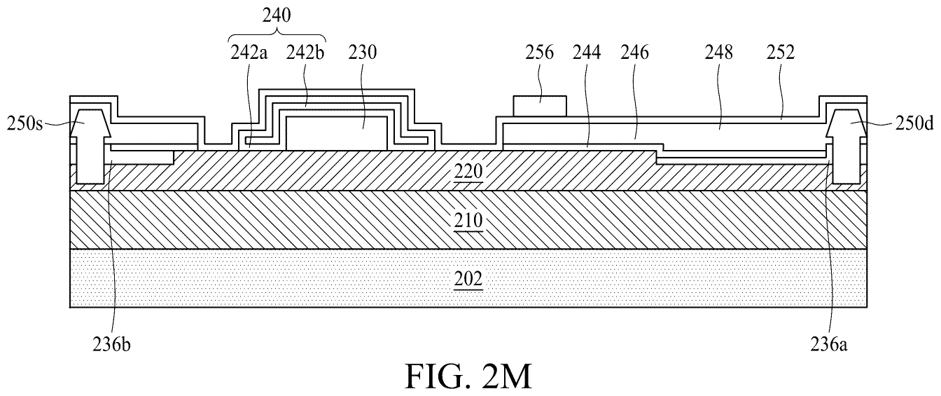

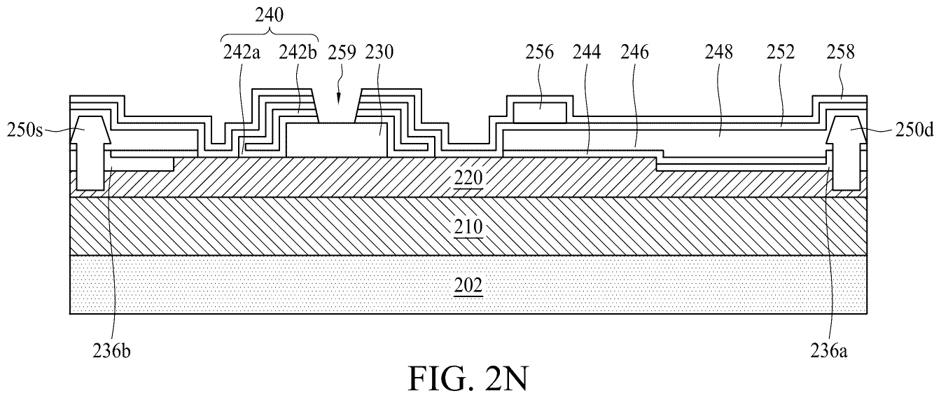

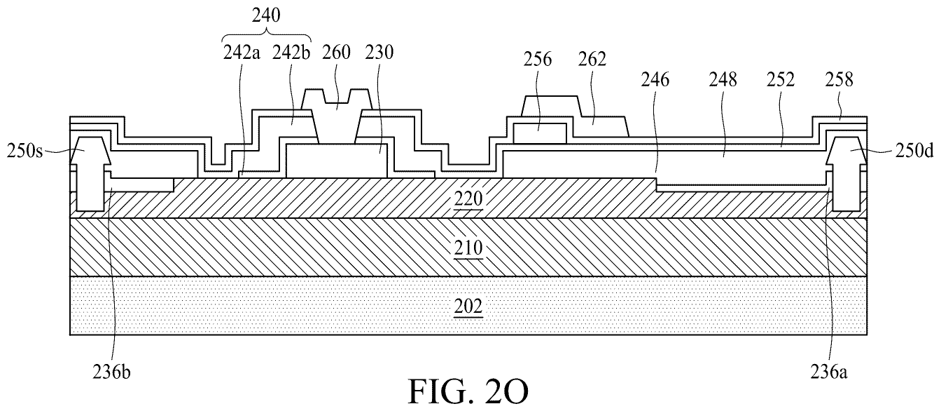

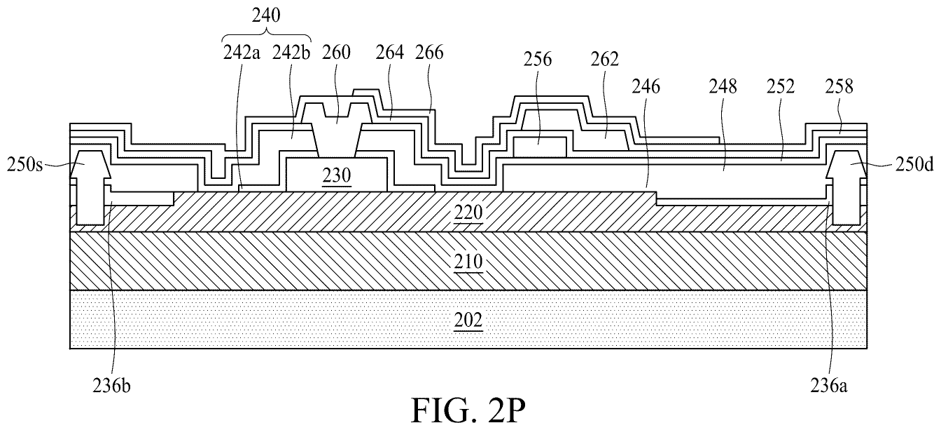

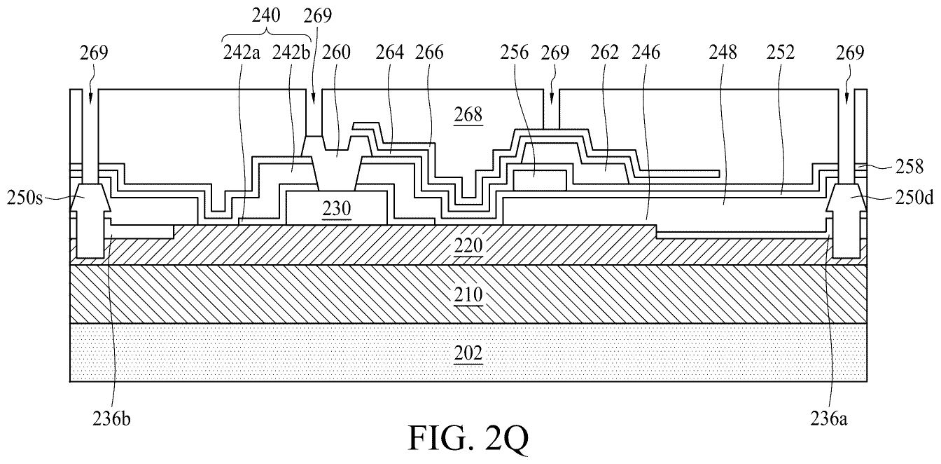

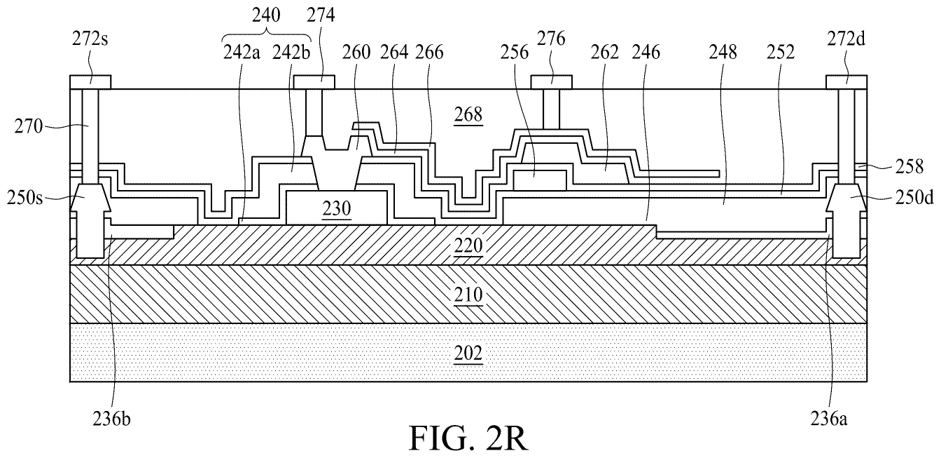

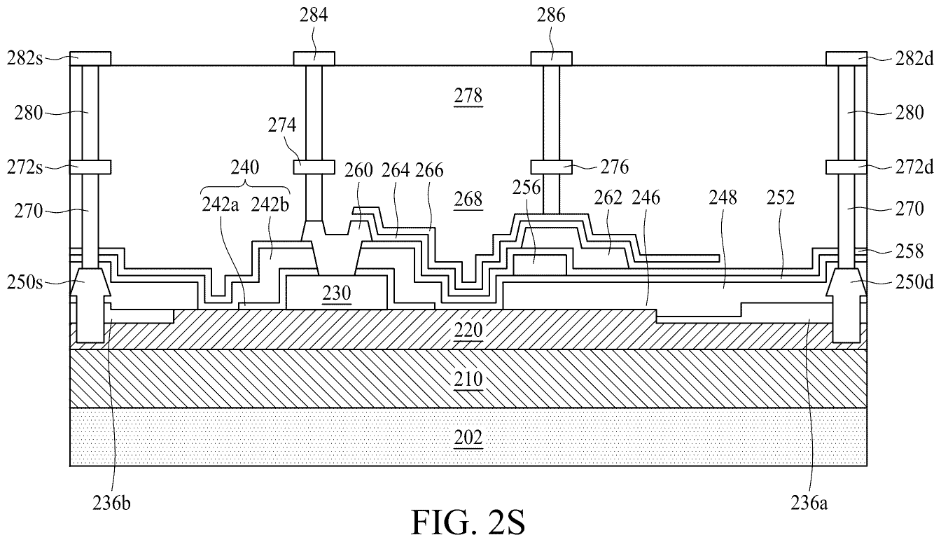

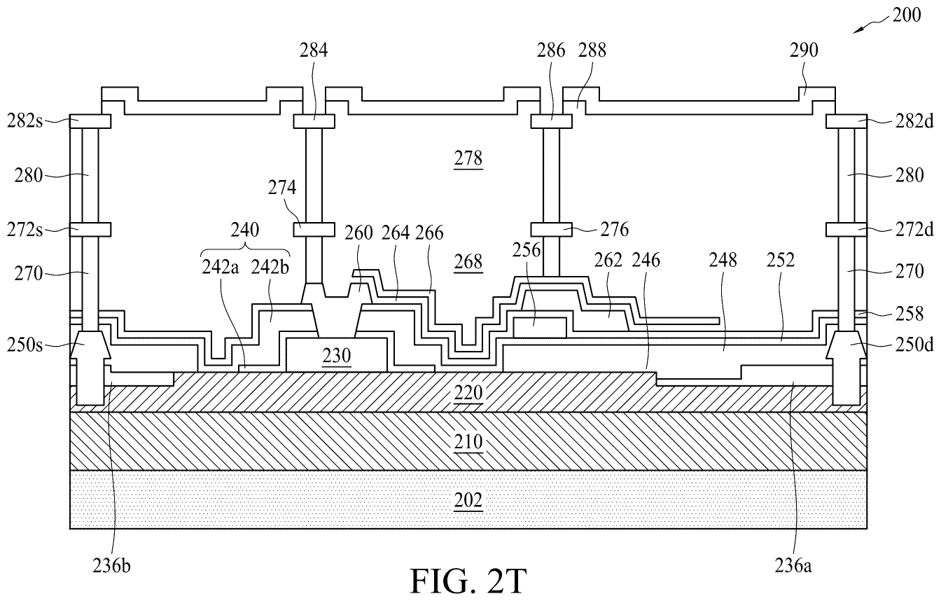

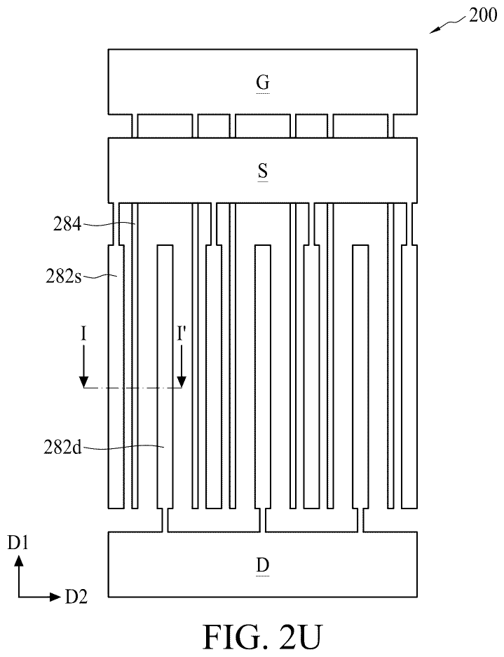

FIGS. 2A to 2U are schematic drawings illustrating a semiconductor structure at various fabrication stages constructed according to aspects of the present disclosure in one or more embodiments. In some embodiments, FIGS. 2A to 2U may represent the methods shown in FIGS. 4 and 5, but the disclosure is not limited thereto.

Referring to FIG. 2A, in some embodiments, a III-V semiconductor layer 210 (i.e., a GaN layer) is formed over a first side 204a of a silicon substrate 202 in operation 21. Details of the silicon substrate 202, and the forming of the III-V semiconductor layer 210 may be similar to those described above; therefore, repeated descriptions are omitted for brevity. It should be noted that a thickness T2 of the III-V semiconductor layer 210 is greater than 7 μm in order to provide sufficient thickness for a device operating in a high-voltage environment, and a thickness T1b of the silicon substrate 202 is greater than 1.15 mm in order to provide sufficient thickness to mitigate a stress issue.

Still referring to FIG. 2A, in some embodiments, after the forming of the III-V semiconductor layer 210, the silicon substrate 202 is thinned from a second side 204b opposite to the first side 204a in operation 22. In some embodiments, operation 22 includes further operations such as, for example but not limited thereto, operations shown in FIGS. 1C to 1F. Accordingly, the thickness T1b of the silicon substrate 202 is reduced from greater than 1.15 mm to less than 1.15 mm. In some embodiments, a thickness difference between the thickness of the silicon substrate 202 prior to the thinning and the thickness T1b of the silicon substrate 202 after the thinning is greater than approximately 15%, but the disclosure is not limited thereto.

As mentioned above, by reducing the thickness of the silicon substrate 202, an overall thickness of the silicon substrate 202 and the III-V semiconductor layer 210 is reduced, such that the structure including the silicon substrate 202 and the III-V semiconductor layer 210 is compatible with requirements of the foundry. For example, the thickness of such structure is suitable for subsequent manufacturing operations.

Referring to FIG. 2A, in some embodiments, in operation 23, another III-V semiconductor layer 220 is formed over the III-V semiconductor layer 210. Details of the forming of the III-V semiconductor layer 220 are similar to those described above; therefore, repeated description is omitted for brevity. In some embodiments, the III-V semiconductor layer 220 includes materials different from those of the III-V semiconductor layer 210. For example but not limited thereto, the III-V semiconductor layer 210 may include GaN, and the III-V semiconductor layer 220 may include AlGaN.

Still referring to FIG. 2A, in some embodiments, a p-type doped III-V semiconductor layer 230 is formed over the III-V semiconductor layer 220. In some embodiments, the p-type doped III-V semiconductor layer 230 may include a p-type doped GaN (p-GaN) layer, and is deposited using techniques such as metal-organic chemical vapor deposition (MOCVD), molecular beam epitaxy (MBE), chemical vapor deposition (CVD), or physical vapor deposition (PVD). A thickness of the p-typed doped III-V semiconductor layer 230 may be between approximately 20 nm and approximately 100 nm, but the disclosure is not limited thereto. In some embodiments, the p-type doped III-V semiconductor layer 230 may include dopants such as carbon (C), iron (Fe), magnesium (Mg), or zinc (Zn) with a concentration ranging from 1E+18 to 1E+21 atoms/cm³, but the disclosure is not limited thereto. To form a p-GaN layer, one would typically start by selecting an appropriate deposition technique like MOCVD, MBE, CVD, or PVD. The chosen method would then be used to deposit a GaN layer with a thickness of about 20 nm to 100 nm. During the deposition process, p-type dopants such as carbon, iron, magnesium, or zinc are introduced to achieve a doping concentration between 1E+18 and 1E+21 atoms/cm³. The doped layer is then epitaxially grown over an active layer, ensuring a consistent doping concentration throughout the layer.

In some embodiments, the p-type doped III-V semiconductor layer 230 is patterned to obtain an island configuration over the III-V semiconductor layer 220. In some embodiments, a mask layer (not shown) is formed on the p-type doped III-V semiconductor layer 230, and the mask layer is patterned to form at least one feature. Next, an etching process is performed to etch the p-type doped III-V semiconductor layer 230 to obtain the island configuration.

Referring to FIG. 2B, in some embodiments, a patterned dielectric layer 232 is formed over the p-type doped III-V semiconductor layer 230 and the III-V semiconductor layer 220. The patterned dielectric layer 232 may include a multilayer. For example, the patterned dielectric layer 232 may include a first dielectric layer 234a and a second dielectric layer 234b over the first dielectric layer 234a. In some embodiments, the first dielectric layer 234a may include an aluminum nitride (AlN) layer 234a, and the second dielectric layer 234b may include a plasma-enhanced oxide (PEOX) layer 234b, but the disclosure is not limited thereto. In such embodiments, a thickness of the second dielectric layer 234b may be greater than a thickness of the first dielectric layer 234a. For example but not limited thereto, the thickness of the first dielectric layer 234a may be approximately 7 angstroms, and the thickness of the second dielectric layer 234b may be approximately 4000 angstroms.

Still referring to FIG. 2B, in some embodiments, the patterned dielectric layer 232 covers sidewalls and a top surface of the p-type doped III-V semiconductor layer 230 and portions of the III-V semiconductor layer 220, such that other portions of the III-V semiconductor layer 220 are exposed. In some embodiments, III-V semiconductor features 236a and 236b may be formed over the portions of the III-V semiconductor layer 220 exposed through the patterned dielectric layer 232. In such embodiments, the III-V semiconductor features 236a and 236b include a material identical to that of the III-V semiconductor layer 220. As shown in FIG. 2B, the III-V semiconductor features 236a and 236b may be formed at two sides of the p-type doped III-V semiconductor layer 230, and are separated from the p-type doped III-V semiconductor layer 230. In some embodiments, an area of the III-V semiconductor feature 236a may be different from that of the III-V semiconductor feature 236b, but the disclosure is not limited thereto.

Additionally, in some embodiments, an etching operation may be performed to recess the portions of the III-V semiconductor layer 220 that are exposed though the patterned dielectric layer 232. In such embodiments, bottom surfaces of the III-V semiconductor features 236a and 236b may be lower than a top surface of the III-V semiconductor layer 220, as shown in FIG. 2B. Further, in such embodiments, top surfaces of the III-V semiconductor features 236a and 236b are lower than top surfaces of the patterned dielectric layer 232.

Referring to FIG. 2C, in some embodiments, a portion of the III-V semiconductor feature 236a is removed, and a portion of the III-V semiconductor feature 236b is removed. Accordingly, a recess 237a is formed in the III-V semiconductor feature 236a, and a recess 237b is formed in the III-V semiconductor feature 236b. In some embodiments, a depth of the recess 237a is equal to a depth of the recess 237b. In some embodiments, a dimension of the recess 237a is greater than a dimension of the recess 237b. The recesses 237a and 237b are formed to adjust an electric field, which is described below.

Additionally, the patterned dielectric layer 232 may be removed prior to the forming of the recesses 237a and 237b, or removed after the forming of the recesses 237a and 237b.

Referring to FIG. 2D, in some embodiments, another patterned dielectric layer 240 is formed over the p-type doped III-V semiconductor layer 230. The patterned dielectric layer 240 may include a multilayered structure. For example, the patterned dielectric layer 240 may include a first dielectric layer 242a and a second dielectric layer 242b over the first dielectric layer 242a. In some embodiments, the first dielectric layer 242a and the second dielectric layer 242b include different materials. For example but not limited thereto, the first dielectric layer 242a may include AlN, and the second dielectric layer 242b may include silicon oxide. In some embodiments, a thickness of the second dielectric layer 242b is greater than a thickness of the first dielectric layer 242a. For example but not limited thereto, the thickness of the first dielectric layer 242a may be approximately 5.5 angstroms, and the thickness of the second dielectric layer 242b may be approximately 2000 angstroms. As shown in FIG. 2D, the patterned dielectric layer 240 covers the sidewalls and the top surface of the p-type doped III-V semiconductor layer 230, and covers portions of the III-V semiconductor layer 220. In such embodiments, portions of the III-V semiconductor layer 220, the III-V semiconductor features 236a and 236b, and the recesses 237a and 237b are exposed through the patterned dielectric layer 240.

In some embodiments, in operation 24, a source electrode and a drain electrode are formed in the III-V semiconductor layer 220. In some embodiments, the forming of the source electrode and the drain electrode includes further operations. For example, referring to FIG. 2E, in some embodiments, a trench 243a and a trench 243b are formed at two sides of the p-type doped III-V semiconductor layer 230. In some embodiments, the trench 243a is formed in the III-V semiconductor feature 236a and separated from the recess 237a. In some embodiments, the trench 243a penetrates the III-V semiconductor feature 236a such that the III-V semiconductor layer 220 is exposed through a bottom of the trench 243a, and the III-V semiconductor layer 220 and the III-V semiconductor feature 236a are exposed through sidewalls of the trench 243a. In some embodiments, the trench 243b is formed in the III-V semiconductor feature 236b and separated from the recess 237b. In some embodiments, the trench 243b penetrates the III-V semiconductor feature 236b such that the III-V semiconductor layer 220 is exposed through a bottom of the trench 243b, and the III-V semiconductor layer 220 and the III-V semiconductor feature 236b are exposed through sidewalls of the trench 243b. In some embodiments, a width of the trench 243a and a width of the trench 243b are the same, but the disclosure is not limited thereto. In some embodiments, a depth of the trench 243a and a depth of the trench 243b are the same, but the disclosure is not limited thereto.

Referring to FIG. 2F, in some embodiments, a dielectric layer 244 and a dielectric layer 246 are sequentially formed over the silicon substrate 202. The dielectric layer 244 and the dielectric layer 246 include different materials. For example but not limited thereto, the dielectric layer 244 includes AlN, and the dielectric layer 246 includes silicon nitride. In some embodiments, a thickness of the dielectric layer 244 is less than a thickness of the dielectric layer 246. For example but not limited thereto, the thickness of the dielectric layer 244 may be approximately 5.5 angstroms, and the thickness of the dielectric layer 246 may be between approximately 800 angstroms and approximately 850 angstroms. The dielectric layer 244 is conformally formed over the silicon substrate 202, such that the sidewalls and the bottoms of the trenches 243a and 243b, the sidewalls and the bottoms of the recesses 237a and 237b, and the top surface of the III-V semiconductor layer 220 is covered by the dielectric layer 244. In some embodiments, the dielectric layer 246 may be conformally formed over the dielectric layer 244. Further, the trenches 243a and 243b, and the recesses 237a and 237b are filled with the dielectric layer 246.

Referring to FIG. 2G, in some embodiments, portions of the dielectric layers 244 and 246 are removed from the trenches 243a and 243b, such that the III-V semiconductor layer 220 is again exposed through the bottoms of the trenches 243a and 243b. The III-V semiconductor layer 220 and the III-V semiconductor feature 236a are again exposed through the sidewalls of the trench 243a, and the III-V semiconductor layer 220 and the III-V semiconductor feature 236b are again exposed through the sidewalls of the trench 243b.

Referring to FIG. 2H, in some embodiments, an ohmic metal layer is formed on the dielectric layer 246, and fills the trenches 243a and 243b. The ohmic metal layer is deposited using a suitable deposition technique such as sputter deposition, evaporation or chemical vapor deposition (CVD). Exemplary ohmic metals include, but are not limited to, Ta, TaN, Pd, W, WSi₂, Ti, Al, TiN, AlCu, AlSiCu and Cu, but the disclosure is not limited thereto. In some embodiments, a post-deposition annealing can be performed on the ohmic metal layer to induce any desirable reactions between the ohmic metal and the adjacent III-V semiconductor layer 220. In some embodiments, the post-deposition anneal may be a rapid thermal annealing (RTA) at an annealing temperature between approximately 800° C. and approximately 900° C.

Still referring to FIG. 2H, in some embodiments, portions of the ohmic metal layer are removed to form ohmic contacts 250d and 250s. The removal process includes performing one or more etching processes. The ohmic contacts 250d and 250s are coupled to the III-V semiconductor layer 220. In some embodiments, the ohmic contacts 250d and 250s are in contact with the III-V semiconductor layer 220. The ohmic contact 250d may be utilized as a part of a drain electrode, and the ohmic contact 250s may be utilized as a part of a source electrode.

Referring to FIG. 2I, in some embodiments, another dielectric layer 248 is formed on the dielectric layer 246. The dielectric layer 248 covers the dielectric layer 246 and the ohmic contacts 250d and 250s. In some embodiments, the dielectric layer 248 can be made of silicon oxide, silicon nitride, silicon oxynitride, silicon carbide, low-dielectric constant dielectric material or a combination thereof. In some embodiments, the dielectric layer 246 and the dielectric layer 248 may include a same material such as, for example but not limited thereto, silicon nitride. In such embodiments, an interface between the dielectric layer 246 and the dielectric layer 248 may be difficult to identify, as shown in FIG. 2I. In some embodiments, the dielectric layer 248 can be formed by a deposition process, such as an ALD process, a CVD process, or a PVD process. In some embodiments, a thickness of the dielectric layer 248 is between about 500 angstroms and about 5000 angstroms, but the disclosure is not limited thereto.

Referring to FIG. 2J, in some embodiments, portions of the dielectric layer 248, portions of the dielectric layer 246 and portions of the dielectric layer 244 are removed. Accordingly, the dielectric layer 246 over the p-type doped III-V semiconductor layer 230 is exposed. Further, portions of the III-V semiconductor layer 220 are exposed.

Referring to FIG. 2K, in some embodiments, another dielectric layer 252 is formed over the silicon substrate 202. The dielectric layer 252 is conformally formed and covers the dielectric layer 248, the portions of the III-V semiconductor layer 220 exposed though the dielectric layer 248, and the dielectric layer 244 over the p-type doped III-V semiconductor layer 230. In some embodiments, the dielectric layer 252 can be made of silicon oxide, silicon nitride, silicon oxynitride, silicon carbide, low-dielectric constant dielectric material or a combination thereof. In some embodiments, the dielectric layer 252 and the dielectric layer 248 may include different materials. For example but not limited thereto, the dielectric layer 248 may include silicon nitride, and the dielectric layer 252 may include silicon oxide. In some embodiments, the dielectric layer 252 can be formed by a deposition process, such as an ALD process, a CVD process, or a PVD process. In some embodiments, a thickness of the dielectric layer 252 may be approximately 1000 angstroms, but the disclosure is not limited thereto. In some embodiments, an anneal may be performed after the forming of the dielectric layer 252, but the disclosure is not limited thereto.

Referring to FIG. 2L, in some embodiments, isolation structures 254 may be formed in the silicon substrate 202, the III-V semiconductor layers 210 and 220 and the dielectric layers 244, 246, 248 and 252. To simplify the drawings, the isolation structures 254 are shown in FIG. 2L, but omitted from FIGS. 2M to 2T.

Referring to FIG. 2M, in some embodiments, a gate field plate 256 is formed on the dielectric layer 252. The forming of the gate field plate 256 may include forming a gate field plate metal layer on the dielectric layer 252, and patterning the gate field plate metal layer. The gate field plate metal layer can be formed by a deposition process, such as an ALD process, a CVD process, or a PVD process. The patterning process includes performing one or more etching processes. The gate field plate 256 can be made of TiN, Ti, Al, AlCu, Cu, or another suitable metal. In some embodiments, the gate field plate 256 is disposed adjacent to but offset from the p-type doped III-V semiconductor layer 230. In some embodiments, the gate field plate 256 is formed between the p-type doped III-V semiconductor layer 230 and one of the ohmic contact 250d. The gate field plate 256 is separated from the III-V semiconductor layer 220 by the dielectric layers 244, 246, 248 and 252.

In some embodiments, in operation 25, a gate electrode is formed over the III-V semiconductor layer 220. In some embodiments, operation 25 include further operations. For example, referring to FIG. 2N, a dielectric layer 258 is formed over the silicon substrate 202. The dielectric layer 258 can be formed by a deposition process, such as an ALD process, a CVD process, or a PVD process. The dielectric layer 258 may be conformally formed over the dielectric layer 258, the portion of the III-V semiconductor layer 220 exposed through the dielectric layers 244, 246, 248 and 252, and the gate field plate 256. In some embodiments, the dielectric layer 258 may include a material different that of the dielectric layer 252. For example but not limited thereto, the dielectric layer 252 may include silicon oxide, and the dielectric layer 258 may include silicon nitride. In some embodiments, a thickness of the dielectric layer 258 may be approximately 800 angstroms, but the disclosure is not limited thereto.

Still referring to FIG. 2N, in some embodiments, a portion of the dielectric layer 258, a portion of the dielectric layer 252, a portion of the dielectric layer 248, a portion of the dielectric layer 246 and a portion of the dielectric layer 244 over the p-type doped III-V semiconductor layer 230 are removed, thereby forming an opening 259. As shown in FIG. 2N, the p-type doped III-V semiconductor layer 230 is exposed through the opening 259.

Referring to FIG. 2O, in some embodiments, a gate metal stack is deposited in the opening 259 and is coupled to the p-type doped III-V semiconductor layer 230. In some embodiments, the gate metal stack may be referred to as a part of a gate electrode 260. As shown in FIG. 2O, the gate electrode 260 is positioned between the drain electrode 250d and the source electrode 250s. The gate electrode 260 can vary in composition. For instance, in some embodiments, the gate electrode 260 may be formed over the p-type doped III-V semiconductor layer 230. Such configuration results in an enhancement mode (E-mode) device. Alternatively, in another embodiment, the gate electrode 260 may be in contact with the III-V semiconductor layer 220. Such configuration results in a depletion mode (D-mode) device. The gate electrode 260 can be made from various metals such as TaN, NiSi, CoSi, Mo, Cu, W, Al, Co, Zr and Pt, and may be formed through deposition processes such as CVD, PVD, ALD, or MOCVD. In some embodiments, the gate electrode 260 may include multiple layers for a composite structure.

In some embodiments, another metal stack 262 can be formed over the dielectric layer 252. The metal stack 262 and the gate electrode 260 can be formed concurrently. Therefore, the metal stack 262 and the gate electrode 260 include a same material. As shown in FIG. 2O, the metal stack 262 may be separated from the gate electrode 260. In some embodiments, the metal stack 262 may overlap the gate field plate 256, but the disclosure is not limited thereto. In some embodiments, the metal stack 262 may serve as a gate field plate, but the disclosure is not limited thereto.

Referring to FIG. 2P, in some embodiments, an inter-layer dielectric (ILD) layer 264 is formed over the silicon substrate 202. In some embodiments, the ILD layer 264 may be formed conformally over the gate electrode 260, the metal stack 262 and the dielectric layer 258. The ILD layer 264 covers the dielectric layer 258 and the gate electrode 260. The ILD layer 264, which may isolate and support conductive features such as subsequently-formed metallization lines, is made of dielectric materials such as oxide, fluorinated silica glass (FSG), SiLK™, SiN, phospho-silicate glass (PSG), boro-silicate glass (BSG), boron-doped phospho-silicate glass (BPSG), or undoped silicate glass (USG). These materials may be deposited using methods such as chemical vapor deposition (CVD), plasma-enhanced CVD (PECVD), or other suitable depositions. In some embodiments, the ILD layer 264 may be made of low dielectric constant (k) materials and can be doped with elements such as carbon, boron, or phosphorus to enhance step coverage and annealing characteristics. An annealing process may be performed to improve electrical insulation properties of the ILD layer 264.

In some embodiments, in operation 26, an interconnect structure is formed over the gate electrode 260, the source electrode 250s and the drain electrode 250d. In some embodiments, operation 26 includes further operations. For example, referring to FIG. 2P, at least a metallization line 266 may be formed over the ILD layer 264. In some embodiments, the metallization line 266 is a part of a lowest metallization layer in the interconnect structure. In such embodiments, the metallization line 266 may be referred to as an M0 layer, but the disclosure is not limited thereto.

Referring to FIG. 2Q, in some embodiments, a dielectric layer 268 may be formed over the metallization line 266. The dielectric layer 268, which may isolate and support conductive features such as subsequently-formed metallization lines, is made of dielectric materials such as oxide, FSG, SiLK™, SiN, PSG, BSG, BPSG, or USG. Such materials may be deposited using methods such as CVD, PECVD, or other suitable deposition methods. In some embodiments, the dielectric layer 268 may be made of low dielectric constant (k) materials and can be doped with elements such as carbon, boron, or phosphorus to enhance step coverage and annealing characteristics. In some embodiments, the dielectric layer 268 may include multiple layers, wherein an etch stop layer (not shown) may be included, but the disclosure is not limited thereto. In some embodiments, to achieve a flattened surface, a chemical mechanical polishing (CMP) process is performed on the dielectric layer 268.

Still referring to FIG. 2Q, in some embodiments, a plurality of via openings 269 are formed in the dielectric layer 268. The via openings 269 can be formed by one or more etching processes. In some embodiments, the source electrode 250s, the gate electrode 260, the metallization line 266 and the drain electrode 250d may be exposed through bottoms of respective via openings 269.

Referring to FIG. 2R, after the via openings 269 are formed in the dielectric layer 268, a metal material is formed to fill the via openings 269 and cover the dielectric layer 268. The metal layer can be formed by one or more deposition processes. The deposition process can be a sputter deposition, evaporation or CVD process. The metal layer may include Ti, Mo, Pt, Cr, W, Ni, Al, AlCu, AlSiCu, Cu, or another suitable material. Still referring to FIG. 2R, in some embodiments, metal layer fills the via openings 269 to form a plurality of via structures 270. Further, the metal layer is patterned and becomes a plurality of metallization lines 272s, 272d, 274 and 276 over the dielectric layer 268. In some embodiments, the metallization lines 272s, 272d, 274 and 276 are referred to as a metallization layer M1 over the metallization layer M0. In some embodiments, the metallization line 272s is electrically connected to the source electrode 250s through one of the via structures 270, the metallization line 274 is electrically connected to the gate electrode 260 through another one of the via structures 270, and the metallization line 272d is electrically connected to the drain electrode 250d through still another one of the via structures 270. In some embodiments, the metallization line 276 is electrically connected to the metallization line 266 through another one of the via structures 270.

Referring to FIG. 2S, in some embodiments, operation 26 further includes forming another dielectric layer over 278 over the metallization layer M1. The dielectric layer 278, which may isolate and support conductive features such as subsequently-formed metallization lines, is made of dielectric materials such as oxide, FSG, SiLK™, SiN, PSG, BSG, BPSG, or USG. Such materials may be deposited using methods such as CVD, PECVD, or another suitable deposition methods. In some embodiments, the dielectric layer 278 may be made of low dielectric constant (k) materials and can be doped with elements such as carbon, boron, or phosphorus to enhance step coverage and annealing characteristics. In some embodiments, the dielectric layer 278 may include multiple layers, wherein an etch stop layer (not shown) may be included, but the disclosure is not limited thereto. In some embodiments, to achieve a flattened surface, a CMP process is performed on the dielectric layer 278.

Still referring to FIG. 2S, in some embodiments, a plurality of via openings (not shown) are formed in the dielectric layer 278. The via openings can be formed by one or more etching processes. In some embodiments, the metallization lines 272s, 272d, 274 and 276 may be exposed through bottoms of respective via openings. After the vias openings are formed in the dielectric layer 278, a metal material is formed to fill the via openings and cover the dielectric layer 278. The metal layer can be formed by one or more deposition processes. The deposition process can be a sputter deposition, evaporation or CVD process. The metal layer may include Ti, Mo, Pt, Cr, W, Ni, Al, AlCu, AlSiCu, Cu, or another suitable material. Still referring to FIG. 2S, in some embodiments, the metal layer filling the via openings forms a plurality of via structures 280. Further, the metal layer is patterned and becomes a plurality of metallization lines 282s, 282d, 284 and 286 over the dielectric layer 278. In some embodiments, the metallization lines 282s, 282d, 284 and 286 are referred to as a metallization layer Mn over the metallization layer M1. In some embodiments, the metallization lines 282s, 282d, 284 and 286 are referred to as a top metallization layer Mtop over the metallization layer Mn. In some embodiments, the metallization line 282s is electrically connected to the source electrode 250s through one of the via structures 270, the metallization line 272s and the via structure 280. The metallization line 284 is electrically connected to the gate electrode 260 through the via structure 270, the metallization line 274 and one of the via structures 280. The metallization line 282d is electrically connected to the drain electrode 250d through the via structure 270, the metallization line 272d and one of the via structures 280. In some embodiments, the metallization line 286 is electrically connected to the metallization line 266 through the via structures 270, the metallization line 276 and one of the via structures 280.

Referring to FIG. 2T, in some embodiments, a dielectric layer 288 and a passivation layer 290 may be sequentially formed over the metallization layer Mn or Mtop. The dielectric layer 288 may include a material same as that of the dielectric layer 278. In some embodiments, the passivation layer 290 may include a material different from that of the dielectric layer 288. For example but not limited thereto, the dielectric layer 288 may include silicon oxide, and the passivation layer 290 may include silicon nitride. In some embodiments, openings may be formed in the dielectric layer 288 and the passivation layer 290, such that the metallization lines 282s, 282d, 284 and 286 are exposed in order to be electrically connected to an external electrical source.

Accordingly, a semiconductor structure 200 is formed, as shown in FIGS. 2T and 2U, wherein FIG. 2U is a top view of the semiconductor structure 200, and FIG. 2T is a cross-sectional view taken along a line I-I′ of FIG. 2U. In some embodiments, the semiconductor structure 200 includes the silicon substrate 202, the III-V semiconductor layer 210 over the silicon substrate 202, the III-V semiconductor layer 220 over the III-V semiconductor layer 210, the gate electrode 260 over the III-V semiconductor layer 220, and the source electrode 250s and the drain electrode 250d coupled to the III-V semiconductor layer 220. In some embodiments, a thickness of the silicon substrate 202 is less than 1.15 mm, which is suitable in the foundry for forming the semiconductor structure 200. In some embodiments, the III-V semiconductor layer 210 includes GaN, and the III-V semiconductor layer 220 includes AlGaN. In some embodiments, the gate electrode 260 is in direct contact with the III-V semiconductor layer 220, and the semiconductor structure is referred to as a D-mode HEMT device. In some alternative embodiments, the p-type doped III-V semiconductor layer 230 is disposed between the gate electrode 260 and the III-V semiconductor layer 220, and the semiconductor structure 200 is referred to as an E-mode HEMT device.

Referring to FIGS. 2T and 2U, the gate electrode 260 is electrically connected to the metallization line 284, the source electrode 250s is electrically connected to the metallization line 282s, and the drain electrode 250d is electrically connected to the metallization line 282d. The metallization lines 282s, 282d and 284 may extend in a first direction D1, and are arranged in a second direction D2 different from the first direction D1, as shown in FIG. 2U. Accordingly, the metallization lines 282s, 282d and 284 are parallel with each other and separated from each other.

In some embodiments, the semiconductor structure 200 may include the source electrode 250s, the gate electrode 260, the drain electrode 250d and related elements periodically arranged. In such embodiments, the metallization lines 282s, 282d and 284 are also periodically arranged in the second direction D2. In some embodiments, the metallization lines 282s are all electrically connected to a line S, the metallization lines 284 are all electrically connected to a line G, and the metallization lines 282d are all electrically connected to a line D, as shown in FIG. 2U.

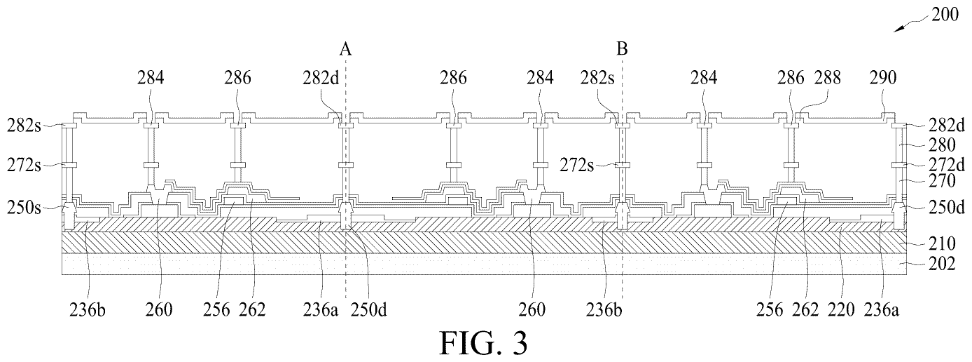

Referring to FIG. 3, in some embodiments, the semiconductor structure 200 may have a symmetric configuration. For example but not limited thereto, elements of the semiconductor structure 200 may be symmetric about an axis A, which is an axis formed of the drain electrode 250d, the via structure 270, the metallization line 270d, the via structure 280, and the metallization line 282d. For example but not limited thereto, elements of the semiconductor structure 200 also may be symmetric about an axis B, which is an axis formed of the source electrode 250s, the via structure 270, the metallization line 272s, the via structure 280, and the metallization line 282s.

The present disclosure provides a method for forming a semiconductor structure for HEMT device. In some embodiments, a silicon substrate is used for forming a thick GaN layer, and a backside grinding operation is used to thin the substrate from its backside. Accordingly, the substrate provides sufficient support during the forming of the GaN layer, and the thinned substrate with the thick GaN layer is able to support the HEMT device in the fab module.

In some embodiments, a method for forming a semiconductor structure is provided. The method includes following operations. A substrate is received. The substrate includes a first side and a second side opposite to the first side. The substrate has a first thickness. A first III-V semiconductor layer is formed over the first side of the substrate. A protection layer is formed over the first III-V semiconductor layer. The protection layer is attached to a carrier. The substrate is thinned from the second side. The substrate has a second thickness after the thinning. A thickness difference between the first thickness and the second thickness is greater than 15%.

In some embodiments, a method for forming a semiconductor structure is provided. The method includes following operations. A first III-V semiconductor layer is formed over a first side of a silicon substrate. The silicon substrate is thinned from a second side opposite to the first side. A second III-V semiconductor layer is formed over the first III-V semiconductor layer. A source electrode and a drain electrode are formed over the second III-V semiconductor layer. A gate electrode is formed over the second III-V semiconductor layer. An interconnect structure is formed over the gate electrode, the source electrode and the drain electrode. The silicon substrate has a first thickness before the thinning, and a second thickness after the thinning. A thickness difference between the first thickness and the second thickness is greater than 15%.

In some embodiments, a semiconductor structure is provided. The semiconductor structure includes a silicon substrate, a first III-V semiconductor layer over the silicon substrate, a second III-V semiconductor layer over the first III-V semiconductor layer, a gate electrode over the second III-V semiconductor layer, and a source electrode and a drain electrode coupled to the second III-V semiconductor layer. A ratio of a thickness of the silicon substrate and a thickness of the first III-V semiconductor layer is between approximately 0.6% and approximately 0.8%.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
receiving a substrate having a first side and a second side opposite to the first side, wherein the substrate has a first thickness;
forming a first III-V semiconductor layer over the first side of the substrate;
forming a protection layer over the first III-V semiconductor layer;
attaching the protection layer to a carrier; and
thinning the substrate from the second side, wherein the substrate has a second thickness after the thinning,
wherein a thickness difference between the first thickness and the second thickness is greater than 15%.

2. The method of claim 1, wherein the substrate comprises silicon.

3. The method of claim 1, wherein the first III-V semiconductor layer comprises gallium nitride (GaN).

4. The method of claim 1, wherein a thickness of the first III-V semiconductor layer is greater than 7 micrometers (μm).

5. The method of claim 1, wherein the first thickness is greater than 1.15 millimeter (mm).

6. The method of claim 1, wherein the second thickness is less than 1.15 millimeters.

7. The method of claim 1, further comprising forming a second III-V semiconductor layer over the first III-V semiconductor layer, wherein the second III-V semiconductor layer is different from the first III-V semiconductor layer.

8. The method of claim 1, further comprising removing the protection layer to expose the first III-V semiconductor layer.

9. A method for forming a semiconductor structure, comprising:
forming a first III-V semiconductor layer over a first side of a silicon substrate;
thinning the silicon substrate from a second side opposite to the first side;
forming a second III-V semiconductor layer over the first III-V semiconductor layer;
forming a source electrode and a drain electrode over the second III-V semiconductor layer;
forming a gate electrode over the second III-V semiconductor layer; and
forming an interconnect structure over the gate electrode, the source electrode and the drain electrode,
wherein the silicon substrate has a first thickness before the thinning and a second thickness after the thinning, and a thickness difference between the first thickness and the second thickness is greater than 15%.

10. The method of claim 9, wherein the first III-V semiconductor layer comprises GaN, and the second III-V semiconductor layer comprises aluminum gallium nitride (AlGaN).

11. The method of claim 9, wherein a thickness of the first III-V semiconductor layer is greater than 7 μm.

12. The method of claim 9, further comprising forming a field plate over the silicon substrate prior to the forming of the gate electrode.

13. The method of claim 9, wherein the forming of the interconnect structure further comprises:
forming a first metallization layer over the silicon substrate; and
forming a second metallization layer over the first metallization layer,
wherein the first metallization layer is separated from the gate electrode, the source electrode and the drain electrode.

14. The method of claim 13, wherein the forming of the second metallization layer further comprises
forming a first metallization line electrically connected to the gate electrode;
forming a second metallization line electrically connected to the source electrode; and
forming a third metallization line electrically connected to the drain electrode.

15. The method of claim 14, wherein the first metallization line, the second metallization line, and the third metallization line are separated from the first metallization layer.

16. A semiconductor structure comprising:
a silicon substrate;
a first Ill-V semiconductor layer over the silicon substrate;
a second III-V semiconductor layer over the first III-V semiconductor layer;
a gate electrode over the second III-V semiconductor layer; and
a source electrode and a drain electrode coupled to the second III-V semiconductor layer,
wherein a ratio of a thickness of the silicon substrate and a thickness of the first III-V semiconductor layer is between approximately 0.6% and approximately 0.8%.

17. The semiconductor structure of claim 16, wherein the first III-V semiconductor layer comprises GaN, and the second III-V semiconductor layer comprises AlGaN.

18. The semiconductor structure of claim 16, wherein a thickness of the second III-V semiconductor layer is less than 30 nm.

19. The semiconductor structure of claim 16, wherein the gate electrode is electrically connected to a first metallization line, the source electrode is electrically connected to a second metallization line, and the drain electrode is electrically connected to the third metallization line.

20. The semiconductor structure of claim 19, wherein the first metallization line, the second metallization line, and the third metallization line are parallel with each other, and separated from each other.
